(19) United States
(12) Patent Application Publication
(10) Pub. No.: US 2012/0234386 A1
(43) Pub. Date: Sep. 20, 2012

(54) STRUCTURAL MEMBER TYPE PHOTOVOLTAIC CURTAIN WALL SYSTEM FOR HIGHER RELIABILITY AND SAFETY LEVEL OF SHIPS

(75) Inventors: Hee-Jin KANG, Gyeryong (KR); Jin Choi, Gyeryong (KR); Jong-Kap Lee, Daejeon (KR)

(73) Assignee: KOREA MARITIME & OCEAN ENGINEERING INSTITUTE, Daejeon (KR)

(21) Appl. No.: 13/050,179

(22) Filed: Mar. 17, 2011

(30) Foreign Application Priority Data
Mar. 15, 2011 (KR) 10-2011-0023031

(51) Int. Cl. H01L 31/0232

(52) U.S. Cl. 136/259

(57) ABSTRACT

Disclosed is a structural member type photovoltaic curtain wall for improving safety and reliability of a ship, the structural member type photovoltaic curtain wall including: a frame functioning as a structural member of an upper structure of a ship; and a solar cell capable of adjusting an angle of incident sunlight with respect to the frame, the solar cell being attached to the frame.

### BACKGROUND OF THE INVENTION

1. Field of the Invention

The present invention relates to a structural member type photovoltaic curtain wall for improving safety and reliability of a ship, which has been improved from the existing photovoltaic curtain wall, used as an exterior material for a building on the ground and applying a load to an exterior wall of the building, and is applied in a form of a structural member to the ship.

2. Description of the Prior Art

Due to the exhaustion of fossil fuels of the present main energy source and the side effects, such as global warming, according to the environmental pollution, the importance of an eco-friendly and highly efficient photovoltaic power generation that does not discharge carbon dioxide at all has been emphasized.

The photovoltaic power generation system (photovolatics) is a power generation system in which panels attached with solar cells are spread in a large scale, so that the electricity is massively generated using the solar energy. That is, the photovoltaic power generation is a scheme of generating the power by using an optoelectronic effect in which the power is generated by the sunlight incident to a solar cell module. A main device of the photovoltaic power generation includes the solar cell module, an inverter for converting a direct current power generated in the solar cell module to an alternating current power, and a structure.

In the meantime, the photovoltaic curtain wall adopting photovoltaic power generation technology has been increasingly applied to a building recently. By directly generating the power from the sunlight by using the photovoltaic curtain wall, it is possible to greatly contribute to the saving of operating costs of a building and the establishment of an eco-friendly city.

However, the existing photovoltaic curtain wall has been used in a form of an exterior material for a building on the ground, and applies the increased load to an exterior wall of the building. Therefore, there is a limitation on the direct application of the photovoltaic curtain wall to a ship, etc. If the photovoltaic curtain wall applies the load to the exterior wall of the ship, not only does the increased load itself directly result in the increase of the total load of the ship, but also the entire load of the ship is further increased due to the installation of an additional structure for reinforcing the ship with the increased load. This leads to the decrease of the loading capacity of a corresponding ship, thereby unavoidably generating the loss in the ship operation.

A prior art related to the photovoltaic curtain wall includes the “Curtain Wall System Adopting Solar Cell Module” assigned Korean Patent Application No. 10-2007-0052092. However, the prior art invention has disadvantages in that it is applied to a building on the ground, the curtain wall is not adopted as a structural member, but applies a load, it is impossible to adjust an angle of incident light, it has no function of storing and supplying power module by module and no function of supplementing the main power. Further, another prior art related to the photovoltaic curtain wall is the “Building Integrated Photovoltaics Curtain Wall System” assigned Korean Patent Application No. 10-2007-0095482, which is also applied to a building on the ground. However, it has a disadvantage in that the curtain wall is not adopted as a structural member, but applies a load, and it is impossible to adjust an angle of a solar cell for collecting sunlight.

### SUMMARY OF THE INVENTION

Accordingly, the present invention has been made to solve the above-mentioned problems occurring in the prior art, and the present invention provides a structural member type photovoltaic curtain wall for improving safety and reliability of a ship, which has been improved from the existing photovoltaic curtain wall, used as an exterior material for a building on the ground and applying a load to an exterior wall of the building, and is applied in a form of a structural member to the ship, thereby efficiently securing the inner space of the ship. Further, according to the present invention, the permeable solar cell is installed in the ship by employing the characteristic of the ship which has no structure blocking the photovoltaic power and can efficiently use the sunlight's reflective effect from the sea surface, etc., thereby supplying the power to a separate compartment instead of a power generator causing noise at night. Furthermore, the present invention plays a role of a modulated emergency power supply source for an emergency incurred by collision, grounding, flooding, fire, etc. of the ship, so that it is possible to reduce the emergency power supply demands required for the current ship.

In accordance with an aspect of the present invention, there is provided a structural member type photovoltaic curtain wall for improving safety and reliability of a ship, the structural member type photovoltaic curtain wall including: a frame functioning as a structural member of an upper structure of a ship; and a solar cell attached to the frame so that an angle of incident sunlight with respect to the frame can be adjusted.

According to the present invention, the permeable solar cell capable of adjusting the incident angle of the sunlight is embedded in the frame functioning as the structural member for use, so that it is possible to secure the wide inside space of the deck of a large passenger ship using a thin plate, and the energy that has been stored during the daytime is used at a time, such as at night, sensitive to the noise and vibration, so that it is possible to improve the calmness of the compartment of the ship's interior. Further, the present invention plays a role of the modulated emergency power supply source, so that it is possible to supplement the power consumption essentially required for the lighting of an emergency light even in the worst situation in which even an emergency power generator is broken in an emergency situation incurrable by an accident, such as collision, grounding, flooding, fire, etc. of the ship, thereby helping people evacuate and shelter in the ship. Therefore, the present invention can greatly improve the reliability and the safety of the ship in the aspects of the power supply and the structure of the ship.

### BRIEF DESCRIPTION OF THE DRAWINGS

The above and other objects, features and advantages of the present invention will be more apparent from the following detailed description taken in conjunction with the accompanying drawings, in which:

FIG. 1 is a view illustrating a construction of a structural member type photovoltaic curtain wall for improving safety and reliability of a ship according to the present invention; and

FIG. 2 is a view illustrating a concept of a structural member type photovoltaic curtain wall for improving safety and reliability of a ship according to the present invention, which supports a structure of a ship's body.

### DETAILED DESCRIPTION OF THE EXEMPLARY EMBODIMENTS

Hereinafter, an exemplary embodiment of the present invention will be described with reference to the accompanying drawings in detail.

According to the present invention, a photovoltaic curtain wall, which has been improved from the existing photovoltaic curtain wall, used as an exterior material for a building on the ground and applying a load to an exterior wall of the building, and is applied in a form of a structural member to the ship, so that the increase of the load of the ship according to the installation of the photovoltaic curtain wall is prevented and a reinforcement structure of a cabin of the ship is simplified, thereby efficiently securing an inner space of the ship. The photovoltaic curtain wall according to the present invention includes a frame 1 and a solar cell 2. Hereinafter, each of the constructional elements will be described in detail.

Frame

The frame 1 itself is an element serving as a framework of the present invention and also playing a role of a structural member of an upper structure, such as a cabin of the ship.

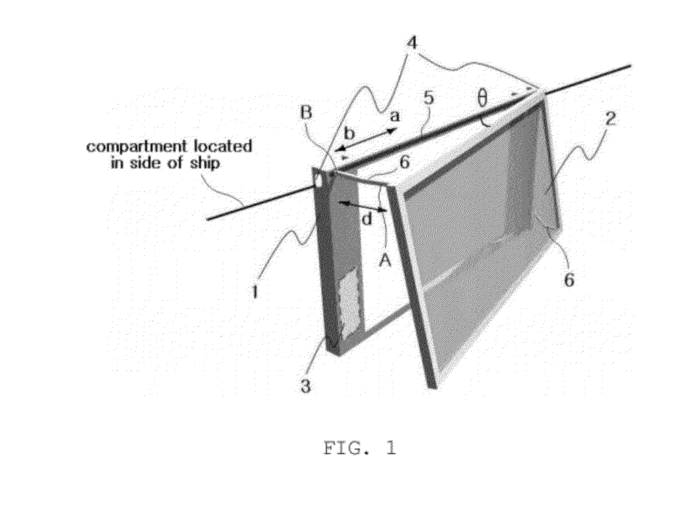

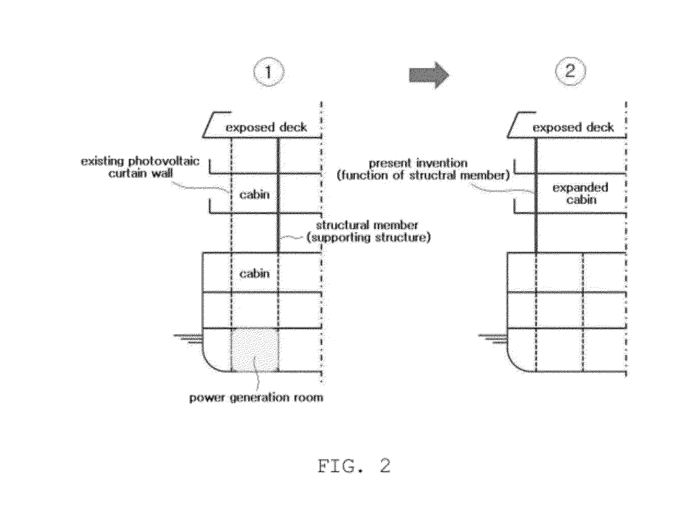

That is, as illustrated in FIGS. 1 and 2, the frame 1 is constructed to be appropriate to a size of a compartment located in the side of the ship and supports an internal structure of the compartment. In this case, the frame 1 must have a sufficient strength to function as the structure.

As described above, if the frame 1 does not apply a load to the ship, but functions as the structural member of the upper structure, such as the cabin of the ship, it is possible to reduce the increase of the entire load of the ship caused by the installation of the present invention and simplify the reinforcement structure of the cabin, so that the inner space of the ship can be efficiently secured.

That is, as illustrated in FIG. 2, when the photovoltaic curtain wall, which has been used as a form of an exterior material for a typical building on the ground and applies a load to an exterior wall of the building, is directly applied to the ship (refer to FIG. 2-\textcircled{1}), it is necessary to additionally install the structural member according to the installation of the photovoltaic curtain wall, so that there occurs a problem that the space of the cabin, etc., is reduced by the additional structural member and thus becomes small and narrow. However, when the frame 1 functions as the structural member of the ship according to the present invention (refer to FIG. 2-\textcircled{2}), it is not necessary to additionally install the structural member, except for the installation of the photovoltaic curtain wall of the present invention, so that it is possible to expand and use the wide space of the cabin, etc. for use in comparison of the case shown in FIG. 2-\textcircled{1}.

In the meantime, the shape of the frame 1 can be variously modified according to the use, but may preferably have a shape of a rectangular frame. In general, the multiple frames 1 are consecutively installed in the compartments arranged in the side of the ship in a rectangular shape and show their functions. Therefore, in this case, when the frames 1 have a shape of a rectangular frame, the loss of the compartment space is not generated in the continuous installation of the frames 1 in upper, lower, left, and right directions and a lattice structure of the installation completed multiple frames 1 advantageously has an effect on the structure of the ship.

Solar Cell

The solar cell 2 is attached to the frame 1 so that an angle of incident sunlight with respect to the frame 1 can be adjusted.

To this end, the frame 1 has a groove 5 having a predetermined length for attachment of the solar cell 2. The solar cell 2 has insertion parts 6, each of which is inserted and fitted in the groove 5 of the frame 1, so as to make the solar cell 2 be attached to the frame 1.

According to the embodiment shown in FIG. 1, the frame 1 has one or more grooves 5 in the edge of a body of the frame 1. The insertion part 6 is a member having a predetermined length, and one end (A) of the insertion part 6 is assembled with the solar cell 2 by a hinge and the other end (B) of the insertion part 6 is inserted and fitted in the groove 5 of the frame 1. As described above, when the other end (B) of the insertion part 6 is inserted and fitted in the groove 5 of the frame 1, the solar cell 2 is attached to the frame 1.

In the meantime, in a state where the solar cell 2 is attached to the frame 1, the other end (B) of the insertion part 6 can move along the groove 5 of the frame 1. That is, in the embodiment shown in FIG. 1, the other end (B) of the insertion part 6 can move in direction a [symbol] b along the groove 5 of the frame 1. In this case, the end (A) of the insertion part 6 is assembled with the solar cell 2 by the hinge, so that it is possible to accept the angle change of the insertion part 6 according to the movement of the other end (B) of the insertion part 6 without difficulty. Further, a bearing is assembled with the other end (B) of the insertion part 6, so that the other end (B) of the insertion part 6 can more smoothly move.

As mentioned above, when the other end (B) of the insertion part 6 moves in direction a [symbol] b along the groove 5 of the frame 1, a distance (d) between the solar cell 2 and the frame 1 is simultaneously changed. That is, in the embodiment of FIG. 1, when the other end (B) of the insertion part 6 moves in direction (a), the distance (d) between the solar cell 2 and the frame 1 is decreased, and when the other end (B) of the insertion part 6 moves in direction (b), the distance (d) between the solar cell 2 and the frame 1 is increased. Based on such operation, it is possible to adjust an angle θ between the solar cell 2 and the frame 1.

As a result, the solar cell 2 according to the present invention can adjust the angle of the incident light. That is, the angle of the solar cell 2 can be adjusted depending on the location of the sunlight. This leads a performance improvement incomparably better than that of the conventional photovoltaic curtain wall that is fixedly attached to a building on the ground in a form of the exterior material and passively generates the power only with the incident light received regardless of the angle of the incident light. Therefore, according to the present invention, it is possible to actively generate the power by using the characteristic of the ship which has no structure blocking the sunlight and the ship can efficiently use the sunlight's reflective effect from the sea surface.

In the meantime, the solar cell 2 of the present invention preferably has the permeability as illustrated in FIG. 1. In this case, the solar cell 2 can simultaneously function as a window of the cabin, so that it has a positive effect on the cabin environment, such as lighting and a view.

Power Storage Device and Power Supply Device

The present invention further includes the power storage device 3 for storing the power collected from the solar cell 2 and the power supply device 4 for supplying the power collected from the solar cell 2 to the outside.

In this respect, the present invention independently supplies the power to the separate compartment and plays a role of a modulated emergency power supply source for an emergency incurable by collision, grounding, flooding, fire, etc. of the ship, instead of a power generator causing noise at night, so that it is possible to save the emergency power supply demands required for the current ship.

In this regard, it is preferred that the power storage device 3 and the power supply device 4 are embedded in the frame 1 as shown in FIG. 1. When the power storage device 3 and the power supply device 4 are embedded in the frame 1, not only can the ship be simply and completely equipped with the aforementioned modulated emergency power supply source through only the installation of the frame 1, but also the ship can have a simple and well-organized appearance because the power storage device 3 and the power supply device 4 are not scattered in the outside after the installation of the frame 1.

### INDUSTRIAL AVAILABILITY

According to the present invention, the photovoltaic curtain wall is implemented in a form of a structural member and applied to the ship, so that it is possible to easily secure the inner space of the ship, increase the power productivity by efficiently using the sunlight's reflective effect, etc., from the sea surface, and play a role of the modulated emergency power supply source for an emergency situation of the ship, thereby improving the safety and the reliability of the ship. Therefore, the present invention is technology that can be widely applied to a naval industry and a photovoltaic power generation industry to realize the practical and economical value of the naval industry and the photovoltaic power generation industry.

Although an exemplary embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A structural member type photovoltaic curtain wall for improving safety and reliability of a ship, the structural member type photovoltaic curtain wall comprising:
a frame functioning as a structural member of an upper structure of a ship; and
a solar cell attached to the frame so that an angle of incident sunlight with respect to the frame can be adjusted.

2. The structural member type photovoltaic curtain wall as claimed in claim 1, further comprising a power storage device to store power collected from the solar cell.

3. The structural member type photovoltaic curtain wall as claimed in claim 2, wherein the power storage device is embedded in the frame.

4. The structural member type photovoltaic curtain wall as claimed in claim 1, further comprising a power supply device to supply power collected from the solar cell to an outside.

5. The structural member type photovoltaic curtain wall as claimed in claim 4, wherein the power supply device is embedded in the frame.

6. The structural member type photovoltaic curtain wall as claimed in claim 1, wherein the frame comprises a groove having a predetermined length for attachment with the solar cell.

7. The structural member type photovoltaic curtain wall as claimed in claim 6, wherein the solar cell comprises insertion parts, each of which is inserted and fitted in the groove, so as to make the solar cell be attached to the frame.

8. The structural member type photovoltaic curtain wall as claimed in claim 7, wherein the insertion part moves along the groove, so that the angle of incident sunlight with respect to the solar cell is adjusted.

9. The structural member type photovoltaic curtain wall as claimed in claim 7, wherein the insertion part has a predetermined length, and one end of the insertion part is assembled with the solar cell by a hinge and another end of the insertion part is inserted and fitted in the groove.

10. The structural member type photovoltaic curtain wall as claimed in claim 9, wherein the another end of the insertion part is assembled with a bearing.

11. The structural member type photovoltaic curtain wall as claimed in claim 1, wherein the solar cell is a permeable solar cell.

12. The structural member type photovoltaic curtain wall as claimed in claim 1, wherein the frame has a shape of a rectangular frame.

13. The structural member type photovoltaic curtain wall as claimed in claim 8, wherein the insertion part has a predetermined length, and one end of the insertion part is assembled with the solar cell by a hinge and another end of the insertion part is inserted and fitted in the groove.
